(19) United States
(12) Patent Application Publication
(10) Pub. No.: US 2012/0133374 A1
(43) Pub. Date: May 31, 2012

(54) METHOD FOR DETECTING CAPACITOR LOSS

(75) Inventors: Chih-Jen Chin, Taipei (TW); Quan-Jie Zheng, Tianjin (CN); Ping Song, Tianjin (CN); Chih-Feng Chen, Taipei (TW)

(73) Assignee: INVENTEC CORPORATION, Taipei (TW)

(21) Appl. No.: 13/070,194

(22) Filed: Mar. 23, 2011

(30) Foreign Application Priority Data
Nov. 30, 2010 (CN) 201010590955.9

(51) Int. Cl. G01R 31/12

(52) U.S. Cl. 324/548

(57) ABSTRACT

A method for detecting a capacitor loss is applicable to detecting a plurality of by-pass capacitors connected in parallel to each other. The detection method includes the following steps, an alternating current (AC) signal is input into the by-pass capacitors, in which the AC signal has a plurality of test frequencies; test voltages of the by-pass capacitors at each of the test frequencies are recorded, so as to form a test result table; it is determined whether the test result table is the same as a standard voltage table; and when a result of the determination is NO, a fail signal is output. By applying the detection method, whether a loss exists in the by-pass capacitors can be effectively identified, thereby solving the problem that small capacitors are undetectable when large capacitors are connected in parallel to the small capacitors.

### CROSS-REFERENCE TO RELATED APPLICATIONS

This non-provisional application claims priority under 35 U.S.C. §119(a) on Patent Application No(s). 201010590955.9 filed in China, P.R.C. on Nov. 30, 2010, the entire contents of which are hereby incorporated by reference.

### FIELD OF THE INVENTION

The present invention relates to a method for detecting a capacitor loss, and more particularly to a detection method for detecting whether a loss exists in a plurality of by-pass capacitors connected in parallel to each other.

### BACKGROUND OF THE INVENTION

Generally, the electrical detection and the inspection operation of appearance and surface defects of a printed circuit board (PCB) must be completed at the factory, in which especially the electrical detection item is currently one of the important steps in the industry to determine the electrical quality of the PCB.

For example, when the PCB is electrically detected by an in-circuit tester, detection items include discrete devices such as a resistor, an inductor, and a capacitor. When the capacitor is detected, as the PCB always has more than one capacitor thereon, in other words, an equivalent capacitor is formed by a plurality of large capacitors and a plurality of small capacitors connected in parallel, in this case, the regular in-circuit tester is incapable of effectively detecting the capacitor.

The reason lies in that, according to Ohm's law, when a plurality of capacitors is connected in parallel, the equivalent capacitance thereof is formed by accumulating the capacitance of each capacitor. For example, when a plurality of capacitors is connected in parallel and respectively has capacitances C1, C2, . . . , and Cn, the equivalent capacitance Cx is C1+C2+ . . . +Cn. However, when the capacitances of the capacitors differ considerably, for example, some are large capacitors and some are small capacitors, and the difference between the capacitance of the large capacitors and that of the small capacitors is more than 1000 times, errors made in the large capacitors themselves may be large enough to cover the capacitances of the small capacitors since the accuracy of the capacitors is generally low (between about −20% and +20%). Therefore, when a conventional phase difference method, a voltage difference method, or a capacitance bridge method is used to measure the total capacitive reactance of the equivalent capacitor, it is impossible to accurately identify whether a loss exists among the small capacitors.

Thus, how to solve the problem resulted from the conventional detection of the capacitors connected in parallel and to provide a detection method capable of accurately identifying a capacitor loss is currently an urgent problem to be solved by persons skilled in the art.

### SUMMARY OF THE INVENTION

Accordingly, the present invention is a method for detecting a capacitor loss, so as to solve the problem existing in the prior art.

The present invention provides a method for detecting a capacitor loss, which is applicable to detecting a plurality of by-pass capacitors connected in parallel to each other. The detection method comprises the following steps: an alternating current (AC) signal is input into the by-pass capacitors, in which the AC signal has a plurality of test frequencies; test voltages of the by-pass capacitors at each of the test frequencies are recorded, so as to form a test result table; it is determined whether the test result table is the same as a standard voltage table; and when a result of the determination is NO, a fail signal is output.

According to the detection method provided by the present invention, the test frequencies may be a plurality of continuous frequencies or a plurality of discrete frequencies.

When the test frequencies are continuous frequencies, the detection method according to an embodiment of the present invention further comprises the following steps: the AC signal is input into a standard capacitor; standard voltages of the standard capacitor at each of the test frequencies are recorded, so as to form the standard voltage table, in which the standard capacitor is at least one of the by-pass capacitors.

When the test frequencies are discrete frequencies, the detection method according to an embodiment of the present invention further comprises the following steps: the AC signal is input into a standard capacitor; standard voltages of the standard capacitor at each of the test frequencies are recorded; and a linear regression is performed according to the test frequencies and the standard voltages, so as to form the standard voltage table, in which the standard capacitor is at least one of the by-pass capacitors.

Therefore, according to the method for detecting the capacitor loss in the present invention, AC properties of the capacitor are utilized, response curves and test results of the by-pass capacitors (that is, capacitors under test) at different frequencies are recorded, and it is further determined whether an abnormal capacitor loss exists through the step of comparing the test result with the standard voltage table, thereby solving the problem that small capacitors are undetectable when large capacitors are connected in parallel to the small capacitors.

### BRIEF DESCRIPTION OF THE DRAWINGS

The present invention will become more fully understood from the detailed description given herein below for illustration only, and thus are not limitative of the present invention, and wherein:

FIG. 1 is a circuit block diagram of a detection circuit according to an embodiment of the present invention;

FIG. 2 is a flow chart of steps of a detection method according to an embodiment of the present invention;

FIG. 3A is a flow chart of steps of forming a standard voltage table in the detection method according to the embodiment of the present invention when test frequencies are continuous frequencies;

FIG. 3B is a circuit block diagram of a detection circuit according to an embodiment of the present invention when a standard voltage table is established;

FIG. 3C is a circuit block diagram of a detection circuit according to an embodiment of the present invention when the standard voltage table is established;

FIG. 3D is a circuit block diagram of a detection circuit according to an embodiment of the present invention when the standard voltage table is established;

FIG. 3E is a circuit block diagram of a detection circuit according to an embodiment of the present invention when the standard voltage table is established;

FIG. 3F is a circuit block diagram of a detection circuit according to an embodiment of the present invention when the standard voltage table is established;

FIG. 4A is a flow chart of steps of forming the standard voltage table in a detection method according to another embodiment of the present invention when the test frequencies are discrete frequencies;

FIG. 4B is a chart of response data in which standard voltages after being normalized are corresponding to test frequencies when a standard capacitor in FIG. 3F loses no by-pass capacitor;

FIG. 4C is a chart of response data in which standard voltages after being normalized are corresponding to test frequencies when a standard capacitor in FIG. 3B loses a by-pass capacitor C1; and

FIG. 4D is a chart of response data in which standard voltages after being normalized are corresponding to test frequencies when a standard capacitor in FIG. 3C loses a by-pass capacitor C2.

### DESCRIPTION OF THE EMBODIMENTS

The detailed features and advantages of the present invention are described below in great detail through the following embodiments, and the content of the detailed description is sufficient for those skilled in the art to understand the technical content of the present invention and to implement the present invention accordingly. Based upon the content of the specification, the claims, and the drawings, those skilled in the art can easily understand the relevant objectives and advantages of the present invention.

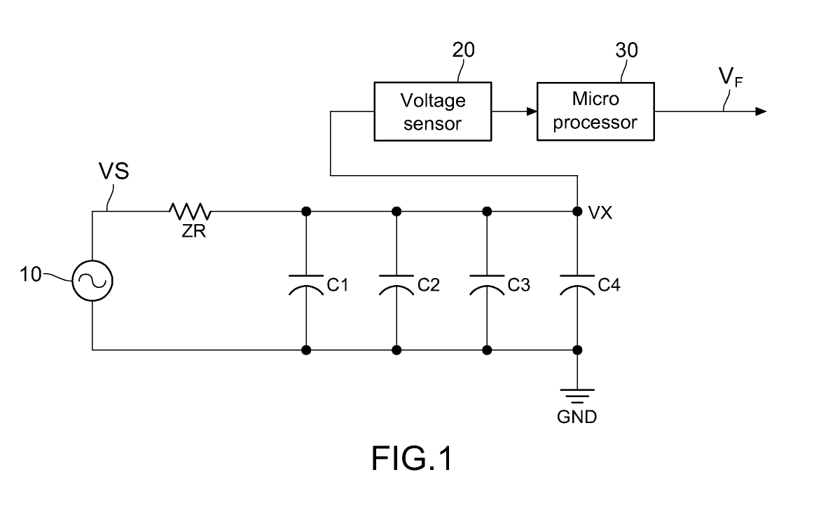

FIG. 1 is a circuit block diagram of a detection circuit according to an embodiment of the present invention. The detection circuit comprises a signal generator (or a signal excitation source) 10, a voltage dividing resistor ZR, a voltage sensor 20, and a micro processor 30. The signal generator 10 is used for providing an AC signal VS; and the voltage dividing resistor ZR is connected between by-pass capacitors C1, C2, C3, and C4 which are connected in parallel to each other and the signal generator 10. The voltage dividing resistor ZR is further connected by the by-pass capacitors C1, C2, C3, and C4 to a ground terminal GND, so as to introduce unnecessary high-frequency noise in the AC signal VS into the ground terminal GND. According to the embodiment of the present invention, the by-pass capacitors C1, C2, C3, and C4 may be regarded as filter capacitors in the detection circuit (or by-pass circuit), and the number thereof is not intended to limit the scope of the present invention. For the convenience of explaining the technical contents of the present invention, the embodiment of the present invention supposes that the number of the by-pass capacitors is four for the following exemplary description.

The micro processor 30 is connected to the voltage sensor 20, and the voltage sensor 20 may be, but is not limited to, an oscillator. The voltage sensor 20 is connected to a common joint of the voltage dividing resistor ZR and the by-pass capacitor C4, so as to detect a divided voltage VX of an equivalent capacitor formed by the by-pass capacitors C1, C2, C3, and C4, in which

$$VX = \frac{Zx}{{Z}_{1} + Zx} \times VS$$

$$Zx = \frac{1}{j 2 π f ( P 1 + P 2 + P 3 + P 4 )}$$

where Z₁ is a resistance of the voltage dividing resistor ZR; P1, P2, P3, and P4 are respectively capacitances of the by-pass capacitors C1, C2, C3, and C4; and f is a frequency of the AC signal VS and may be a plurality of different frequencies f1, f2 . . . fn.

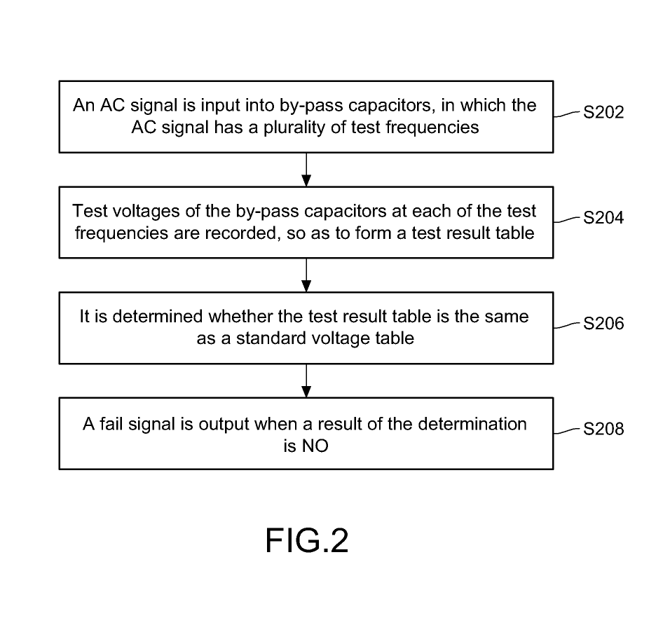

FIG. 2 is a flow chart of steps of a detection method according to an embodiment of the present invention. The detection method is applicable to detecting whether a loss exists in the by-pass capacitors C1, C2, C3, and C4 which are connected in parallel to each other in FIG. 1. Referring to FIG. 2, the detection method comprises the following Steps S202 to S208.

In Step S202, an AC signal is input into by-pass capacitors, in which the AC signal has a plurality of test frequencies.

In Step S204, test voltages of the by-pass capacitors at each of the test frequencies are recorded, so as to form a test result table.

In Step S206, it is determined whether the test result table is the same as a standard voltage table.

In Step S208, when a result of the determination is NO, a fail signal is output.

In the detection circuit in FIG. 1 and the detection method in FIG. 2 according to the embodiment of the present invention, in Step S202, the AC signal VS is input into the by-pass capacitors C1, C2, C3, and C4, in which the AC signal VS has a plurality of test frequencies f1, f2 . . . fn. Next, in Step S204, the voltage sensor 20 records a test voltage of the equivalent capacitor formed by the by-pass capacitors C1, C2, C3, and C4 at each of the test frequencies f1, f2 . . . fn, and then transfers the test results to the micro processor 30 so as to form a test result table in which the test frequencies are corresponding to the test voltages. Then, in Step S206, the micro processor 30 determines whether the test result table is the same as a standard voltage table according to the test result table. Finally, when a result of the determination is NO, as shown in Step S208, the micro processor 30 outputs a fail signal V_{F} to indicate that there may be capacitors lost or damaged among the by-pass capacitors C1, C2, C3, and C4.

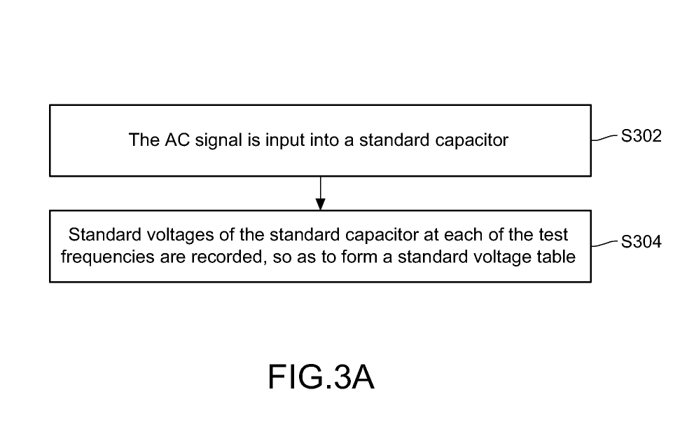

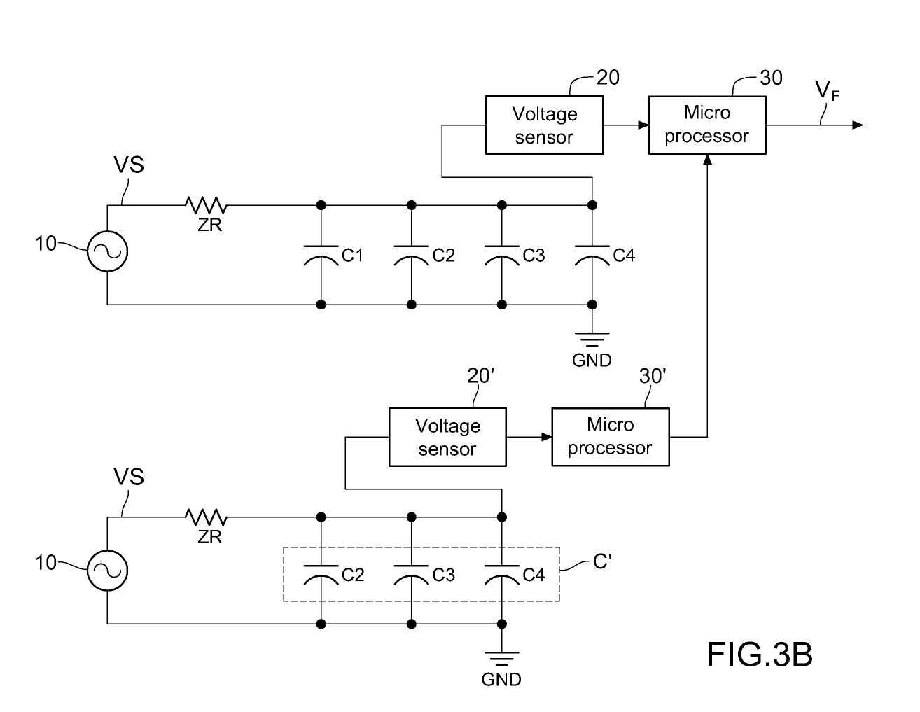

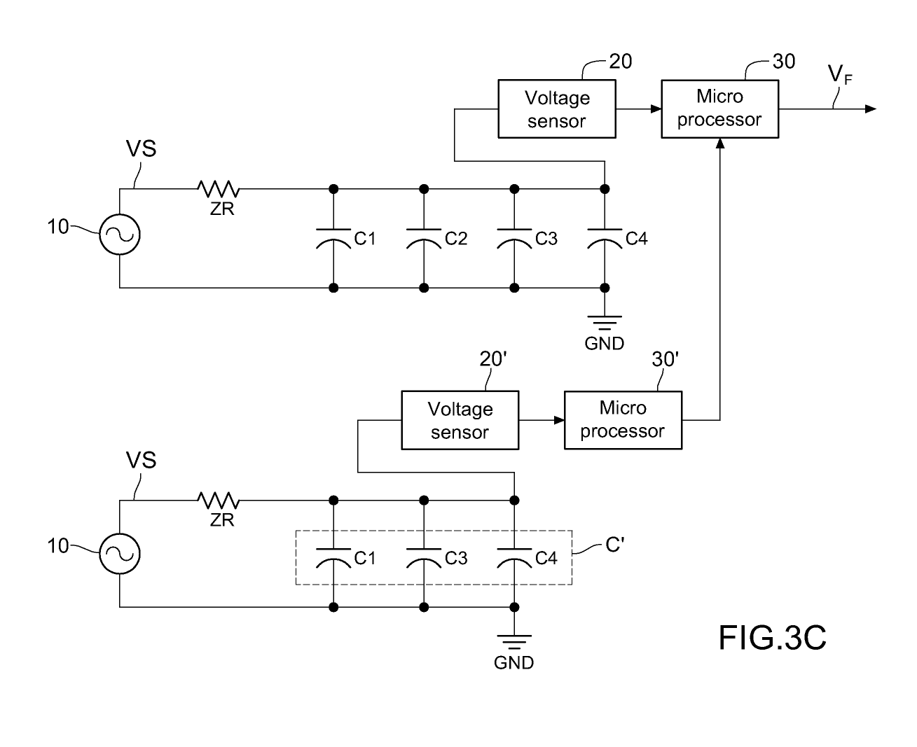

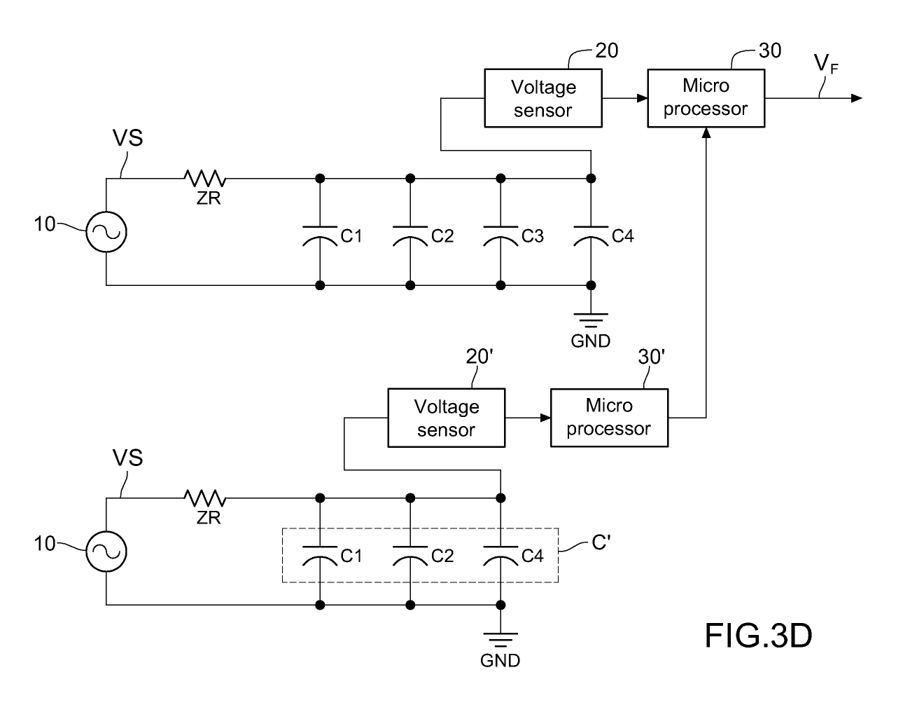

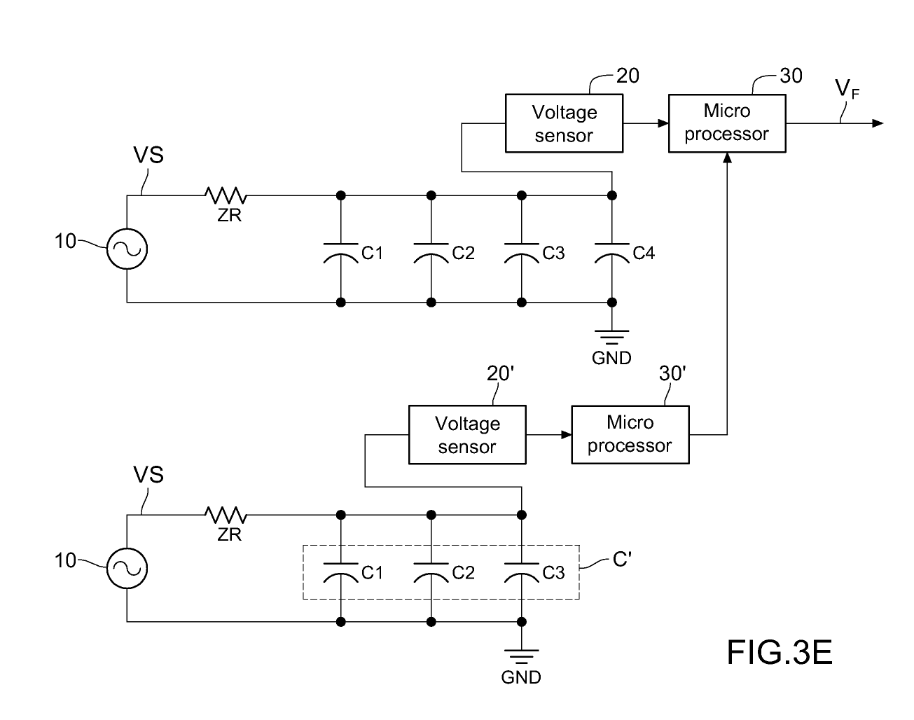

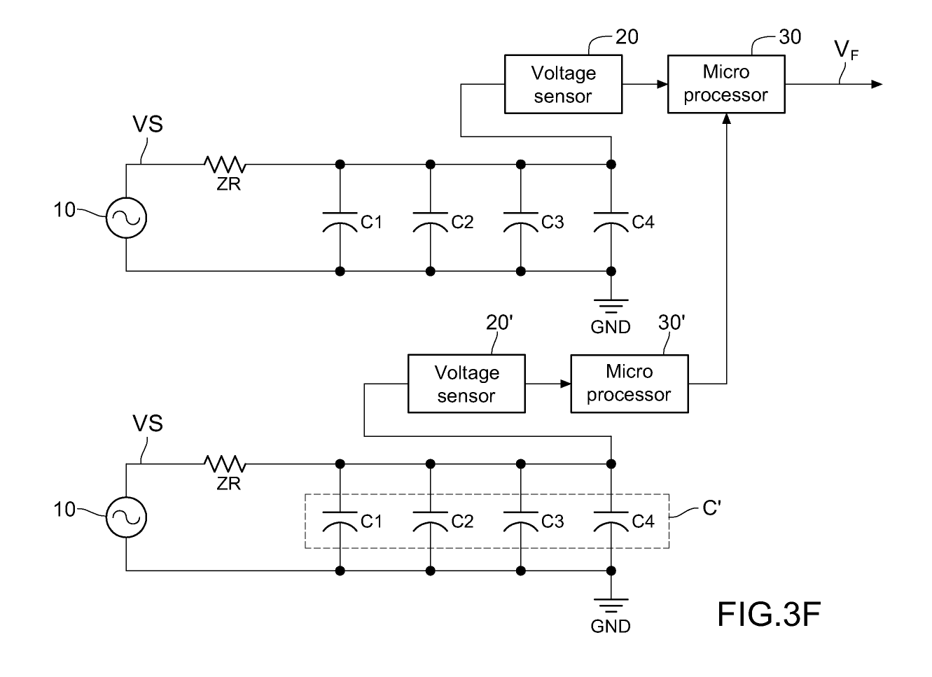

Specifically, the standard voltage table may be a comparison data table established in the micro processor 30 or a comparison data table formed in a manner described in the following two embodiments respectively according to the test frequencies of the AC signal VS. FIG. 3A is a flow chart of steps of forming a standard voltage table in the detection method according to the embodiment of the present invention when the test frequencies are continuous frequencies. Referring to FIG. 3A together with the detection circuit in FIGS. 3B to 3F, firstly in Step S302, the AC signal VS is input into a standard capacitor C′; and in Step S304, a voltage sensor 20′ records standard voltages of the standard capacitor C′ at each of the test frequencies, so that a micro processor 30′ forms the standard voltage table according to the test frequencies and the corresponding standard voltages.

The standard capacitor C′ may comprise the by-pass capacitors C2, C3, and C4 (losing the by-pass capacitor C1) as shown in FIG. 3B; comprise the by-pass capacitors C1, C3, and C4 (losing the by-pass capacitor C2) as shown in FIG. 3C; comprise the by-pass capacitors C1, C2, and C4 (losing the by-pass capacitor C3) as shown in FIG. 3D; comprise the by-pass capacitors C1, C2, and C3 (losing the by-pass capacitor C4) as shown in FIG. 3E; or comprise the by-pass capacitors C1, C2, C3, and C4 (losing no capacitors) as shown in FIG. 3F. The selection of the standard capacitor C′ is not limited to the above manners, and a tester is free to design the standard capacitor C′ as at least one of the by-pass capacitors C1, C2, C3, and C4.

Therefore, according to the embodiment of the present invention, the micro processor 30 with the test result table stored therein may compare whether the test result table is the same as the standard voltage table by electrically connecting to the micro processor 30′ with the standard voltage table stored therein, and output the fail signal V_{F} when they are not the same. For example, when the test result table is different from the standard voltage table formed by the micro processor 30′ in FIG. 3F, the micro processor 30 outputs the fail signal V_{F} to indicate that there may be capacitors lost or damaged among the by-pass capacitors C1, C2, C3, and C4. Furthermore, if the test result table is compared with the standard voltage table formed by the micro processor 30′ in FIG. 3B and they are the same, the tester determines that the lost capacitor is the by-pass capacitor C1.

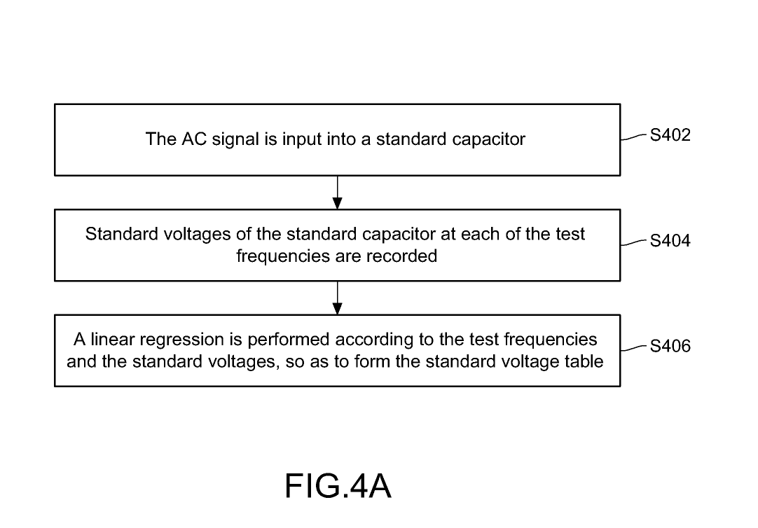

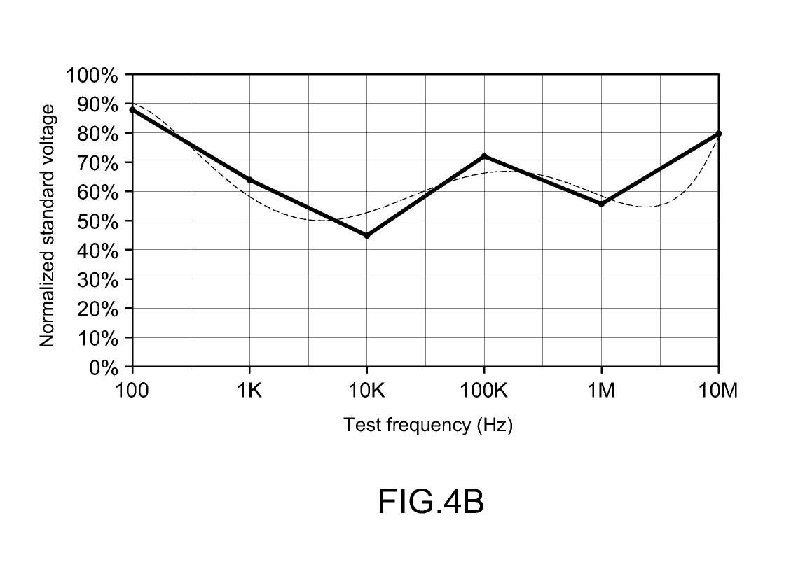

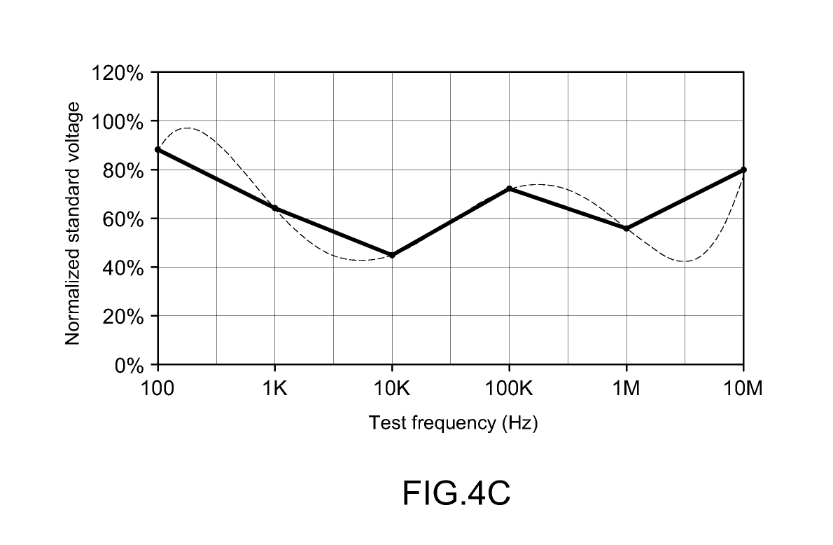

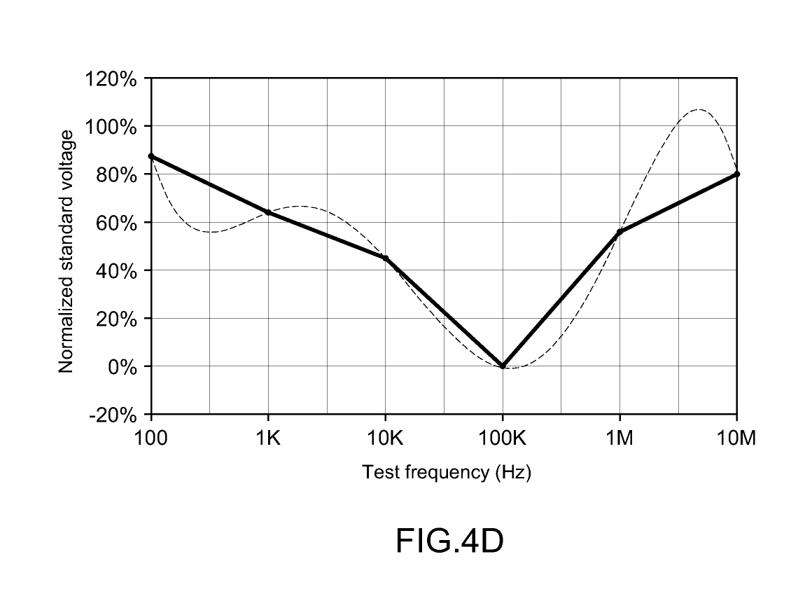

Since the test result table and the standard voltage table established with the continuous test frequencies may have too large databases, which increases the complexity of the calculation, FIG. 4A is a flow chart of steps of forming a standard voltage table in the detection method according to another embodiment of the present invention when the test frequencies are discrete frequencies. Similarly, referring to FIG. 4A together with the detection circuit in FIGS. 3B to 3F, firstly in Step S402, the AC signal VS is input into a standard capacitor. Next, in Step S404, the voltage sensor 20′ records standard voltages of the standard capacitor at each of the test frequencies. Then, in Step S406, the micro processor 30′ performs a linear regression (or curve fitting) according to the test frequencies and the corresponding standard voltages, so as to form the standard voltage table. The standard capacitor may be selected from the by-pass capacitors in FIGS. 3B to 3F as described in the previous embodiment, and thus the details will not be repeated herein again.

FIGS. 4B to 4D are respectively charts of response data in which standard voltages after being normalized are corresponding to test frequencies when the standard capacitor in FIG. 3F loses no capacitors, the standard capacitor in FIG. 3B loses the by-pass capacitor C1, and the standard capacitor in FIG. 3C loses the by-pass capacitor C2. The solid line shows a curve formed by a plurality of standard voltages actually measured at discrete frequencies; and the dashed line shows a predicted curve formed after a linear regression of polynomial analysis is performed according to the measured data of the solid line. Thus, as shown in FIGS. 4B to 4D, the predicted curves after the linear regression are respectively:

y=−0.168x4+1.001x3−2.590x2+2.651x,

y=0.025x5−0.431x4+2.749x3−7.943x2+10.04x−0.356, and

y=−0.034x5+0.588x4−3.670x3+10.47x2−13.71x+7.24.

The micro processor 30′ may capture the coefficients of the predicted curves of the polynomials to serve as the standard voltage table used in the test comparison.

In addition, in Step S206, when the test result table is compared with the standard voltage table, the determination may be made by performing precise comparison (namely, the test voltage corresponding to each of the test frequencies should be equal to the standard voltage) or performing the comparison step according to an allowable error, that is to say, if the test voltage corresponding to each of the test frequencies stays within the allowable error range of the standard voltage, it is determined that they are the same. Therefore, the designer is free to decide the allowable error during the comparison according to the precision required by the detection.

Specifically, in the detection method according to the present invention, when the number of the by-pass capacitors is too large, or when the calculation workload of the micro processor cannot support a great number of comparison databases (comprising those of the test result table and the standard voltage table), the detector may choose to first carry out routine detection on the measurable large capacitors in the by-pass capacitors in advance. When the large capacitors are tested as normal, the detector is only required to perform the detection method as described above in the present invention on small capacitors. In this way, not only the cost of establishing the comparison databases is effectively saved, but also the efficiency of the detection operation is improved.

To sum up, according to the detection method provided by the present invention, the AC signal generated by the signal generator is input into the by-pass capacitors, and the test voltages of the by-pass capacitors at different frequencies are recorded through the voltage sensor so as to form the test result table. By comparing whether the test result table is the same as the standard voltage table, the detection method provided by the present invention can identify whether a loss exists in the by-pass capacitors, so as to solve the problem that small capacitors are undetectable when large capacitors are connected in parallel to the small capacitors.

What is claimed is:

1. A method for detecting a capacitor loss, applicable to detecting a plurality of by-pass capacitors connected in parallel to each other, comprising:
inputting an alternating current (AC) signal into the by-pass capacitors, wherein the AC signal has a plurality of test frequencies;
recording test voltages of the by-pass capacitors at each of the test frequencies, so as to form a test result table;
determining whether the test result table is the same as a standard voltage table; and
outputting a fail signal when a result of the determination is NO.

2. The method according to claim 1, wherein the test frequencies are a plurality of continuous frequencies.

3. The method according to claim 2, further comprising:
inputting the AC signal into a standard capacitor; and
recording standard voltages of the standard capacitor at each of the test frequencies, so as to form the standard voltage table,
wherein the standard capacitor is at least one of the by-pass capacitors.

4. The method according to claim 1, wherein the test frequencies are a plurality of discrete frequencies.

5. The method according to claim 4, further comprising:
inputting the AC signal into a standard capacitor;
recording standard voltages of the standard capacitor at each of the test frequencies; and
performing a linear regression according to the test frequencies and the standard voltages, so as to form the standard voltage table,
wherein the standard capacitor is at least one of the by-pass capacitors.
